(19) United States
(12) Patent Application Publication
(10) Pub. No.: US 2025/0079330 A1
(43) Pub. Date: Mar. 6, 2025

(54) EMBEDDED CHIP-PACKAGE, SEMICONDUCTOR PACKAGE, METHOD OF FORMING AN EMBEDDED CHIP-PACKAGE, METHOD OF FORMING A SEMICONDUCTOR PACKAGE, AND METHOD OF ANALYZING AN EMBEDDED CHIP-PACKAGE OR A SEMICONDUCTOR PACKAGE

(71) Applicant: Infineon Technologies AG, Neubiberg (DE)

(72) Inventors: Mahadi-Ul HASSAN, Regensburg (DE); Mark PAVIER, East Grinstead (GB)

(73) Assignee: Infineon Technologies AG, Neubiberg (DE)

(21) Appl. No.: 18/806,062

(22) Filed: Aug. 15, 2024

(30) Foreign Application Priority Data
Aug. 29, 2023 (DE) 10 2023 123 227.4

(51) Int. Cl. H01L 23/544; H01L 23/31; H01L 23/498

(52) U.S. Cl. CPC H01L 23/544; H01L 23/3107; H01L 23/49838; H01L 23/49861; H01L 2223/54446

(57) ABSTRACT

An embedded chip-package is provided. In one example, the embedded chip-package includes a chip, an electrically insulating material at least partially encapsulating the chip, at least one metal layer configured to provide at least one electrically conductive connection to the chip, and an information section. The information section includes coded information about the embedded chip-package, wherein, in the information section, the information is coded as a pattern of electrically conductive portions and electrically insulating portions.

### CROSS-REFERENCE TO RELATED APPLICATION

This Utility Patent Application claims priority to German Patent Application No. 10 2023 123 227.4 filed Aug. 29, 2023, which is incorporated herein by reference.

### TECHNICAL FIELD

Various embodiments relate generally to an embedded chip-package, a semiconductor package, a method of forming an embedded chip-package, a method of forming a semiconductor package, and to a method of analyzing an embedded chip-package or a semiconductor package.

### BACKGROUND

Semiconductor devices, for example D2pak, TO220, PQFNs, are typically marked, using for example a laser for marking mold material of the semiconductor device, with information that makes it possible to identify the device.

The information may for example include device type, date of manufacture, lot detail, etc. The information may for example be written using alphanumeric characters, or as a data matrix code (DMC). After these devices are assembled on a circuit board, the information is still easily readable by a user, if required. So, this enables full tracability of each component assembled onto the circuit board.

Typically, these devices are configured as plastic encapsulated packages and usually include a metal leadframe with attached and wire bonded dies (also referred to as chips). The leadframe with the mounted chips is then usually overmolded with a plastic mold compound. After the molding process, the semiconductor devices are singulated and tested. The mold compound is then laser marked with the device marking, date code and manufacturer's logo. Other process flows loosely connected to the mentioned process flow may additionally or alternatively be used.

This kind of semiconductor package may have disadvantages like high parasitics, high losses, and/or a bulky form factor.

In order to create very small footprint applications with high power density, it is possible to create embedded circuits within a printed circuit board.

Semiconductor (e. g., silicon) chips may be embedded into a laminate package in a so called embedded chip-package, which may form an inlay that may then be laminated into the final printed circuit board (PCB).

This technology may enable an integration of multiple devices into the PCB in a 3D configuration.

The embedded chip-package may offer significantly lower parasitics with better efficiency and/or a small form factor.

One primary challenge of the inlay technology may be to identify and trace down a device that is embedded into a PCB. Depending on the size of the pre-packaged inlay, it may be possible to add a device marking using the laser marking process mentioned above. But as soon as the pre-packaged inlay is embedded into the PCB, the device marking is invisible, since the PCB materials are not optically tranparent.

It may be possible to tear down the PCB (e.g. by chemically etching away the layers that cover the marking) and thereby uncover the marking, but this is a destructive process and will result in damage to the circuit.

This means that, using the conventional marking approach, it is no longer possible to identify an embedded chip-package that is embedded in a PCB while the PCB is in operation or at least remains in a functional state.

### SUMMARY

An embedded chip-package is provided. The embedded chip-package includes a chip, an electrically insulating material at least partially encapsulating the chip, at least one metal layer configured to provide at least one electrically conductive connection to the chip, and an information section including coded information about the embedded chip-package, wherein, in the information section, the information is coded as a pattern of electrically conductive portions and electrically insulating portions.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic top view of an embedded chip-package in accordance with various embodiments;

FIG. 1B shows a schematic cross-sectional view of the embedded chip-package of FIG. 1A;

FIG. 2A shows a schematic top view of an embedded chip-package in accordance with various embodiments;

FIG. 2B shows a schematic cross-sectional view of the embedded chip-package of FIG. 2A;

FIG. 3A shows a schematic top view of an embedded chip-package in accordance with various embodiments;

FIG. 3B shows a schematic cross-sectional view of the embedded chip-package of FIG. 3A;

FIG. 3C shows a schematic cross-sectional view of a core of the embedded chip-package of FIGS. 3A and 3B;

FIG. 4A shows a schematic top view of an embedded chip-package in accordance with various embodiments;

FIG. 4B shows a schematic cross-sectional view of the embedded chip-package of FIG. 4A;

FIG. 4C shows a schematic cross-sectional view of a core of the embedded chip-package of FIGS. 4A and 4B;

FIG. 5 shows a schematic cross-sectional view of a semiconductor package in accordance with various embodiments; and

FIG. 6 shows a flow diagram of a method of forming an embedded chip-package in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In various embodiments, an embedded chip-package for embedding into a PCB is provided.

The term “embedded chip-package” is to be understood to describe a structure, e.g., a package that includes an embedded chip (as opposed to a chip package that has the characteristic of being embedded).

The term “semiconductor package” is to be understood to refer to a package that includes an embedded chip-package.

In various embodiments, a marking system is provided that is integrated in an embedded chip-package (also referred to as inlay or prepackaged device), so that later during operation phase, the particular device may be identified and traced back.

In various embodiments, individual (e. g., tracability) information for each device may be engraved on inner layers of the package while manufacturing. The information may be retrieved using non-visual imaging techniques like, for example, X-ray- and/or ultrasonic imaging of the device, or using sectioning during failure analysis.

The (e. g., tracability) information may in various embodiments be provided (e. g., engraved and/or etched) in or on an embedded chip-package in one or more of several ways. For example, coded information may be provided by changing the laser/mechanical via diameter landing on the chip and/or on an outside of the embedded chip-package and forming a DataMatrix Code (DMC), and/or by arranging a shape of an identifiable character. Alternative or additional ways include dummy/half drilled laser/mechanical vias on metal layer structures and engraving on inner and/or outer unused metal layers, characters and/or dot matrix code.

As another way to phrase it, information (e. g. coded information) may be provided inside or on an outside of an embedded chip-package by modifying functional metal structures of the embedded chip-package, and/or by arranging additional non-functional metal structures inside or on an outside of the embedded chip-package. Functional/non-functional, in this contrext, refers to an operation of the embedded chip-package. Functional metal structures may for example include or consisit of redistribution layers, metal thermal interface layers, metal shielding layers and/or vertical interconnects (e. g., vias), and non-functional metal structures may for example include or consist of dummy vias, metal layers (e. g., floating metal layers) and/or other metal structures that may be arranged inside or on an outer surface of the embedded chip-package without electrical functionality for the embedded chip-package.

Even though the structures carrying the information inside or on the embedded chip-package are described herein as metal structures, since metals are known to have an atomic number Z and/or a density that is high enough to make them distinguishable from a low-Z (e. g. carbon-rich) environment in non-visual imaging techniques, it is to be understood that, as an alternative, non-metal materials that are distinguishable, e. g. due to a difference in atomic number and/or density, as compared to a surrounding medium, in non-visual imaging, like X-ray imaging and/or ultrasonic imaging, may be used, at least for the non-functional structures.

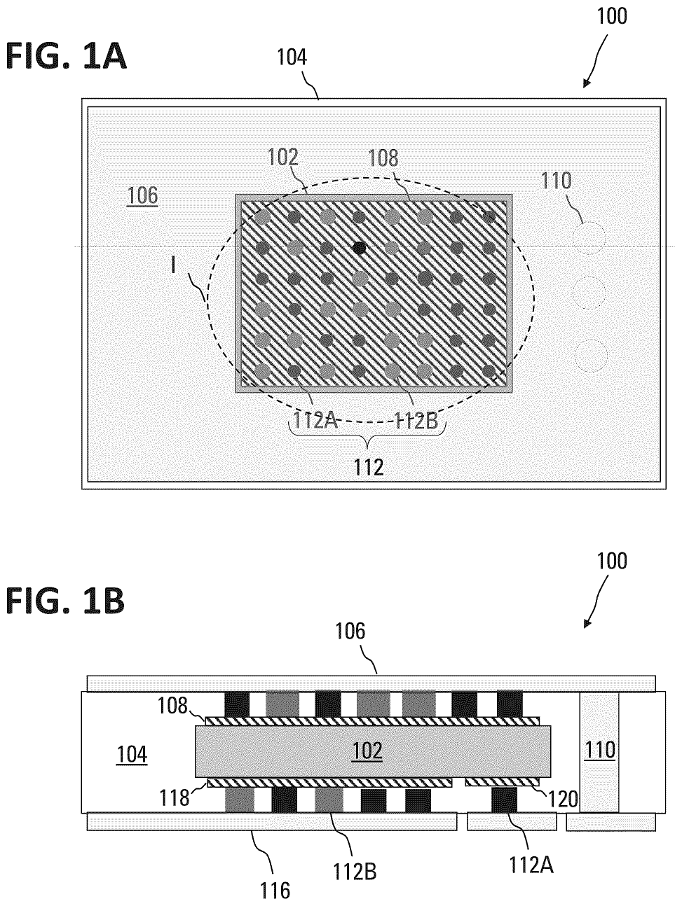

FIG. 1A shows a schematic top view of an embedded chip-package 100 in accordance with various embodiments, and FIG. 1B shows a schematic cross-sectional view of the embedded chip-package 100 of FIG. 1A along the horizontal line in FIG. 1A.

The embedded chip-package 100 includes a chip 102, for example a semiconductor chip that may include or consist of an electronic device or an integrated circuit.

The embedded chip-package 100 further includes an electrically insulating material 104 at least partially encapsulating the chip 102. The electrically insulating material 104 may for example include or consist of a mold material that may essentially be configured as known in the art, optionally a laminate layer. Mold materials are typically carbon-based materials, e. g. polymers, such that their atomic number may be around Z=6, the atominc number of carbon, with densities in a range from about 0,9 g/cm³ to about 1,5 g/cm³.

The embedded chip-package 100 further includes at least one metal layer 106, 116 configured to provide at least one electrically conductive connection to the chip 102.

The at least one metal layer 106 may for example be at least partially exposed on an outer surface of the embedded chip-package 100 or connected to a structure that is exposed on an outer surface of the embedded chip-package 100. In various embodiments, the at least one metal layer 106, 116 may not be exposed on an outer surface of the embedded chip-package 100, but may be contacted, e. g. by an interconnect, e. g. a vertical interconnect (which may extend between main surfaces of the embedded chip-package 100, for example orthogonal to a plane that is parallel to one or both main surfaces of the embedded chip-package 100), once the embedded chip-package 100 is in its final functional configuration, e. g., embedded in a PCB.

The at least one metal layer 106, 116 may for example be configured as a redistribution layer (RDL). The at least one metal layer 106, 116 may for example include or consist of copper, silver, gold, aluminum, alloys and/or other combinations thereof (e. g., layer stacks), and may generally be essentially configured as known in the art, except for differences that may be outlined herein.

The embedded chip-package 100 further includes an information section I including coded information about the embedded chip-package 100, wherein, in the information section I, the information is coded as a pattern of electrically conductive portions and electrically insulating portions.

As mentioned above, in a more general sense, the pattern may not necessarily need to be formed from electrically conductive and electrically insulating portions, but it may rather be sufficient to use two (or more) materials that are distinguishable in non-visual imaging techniques like X-ray or ultrasound. For example, aluminum-(Z=13)- and/or silicon-(Z=14)-based non-metals like aluminum oxide and/or silicon oxide may be sufficiently distinguishable from a surrounding carbon-(Z=6)-based material, and hence be suitable for creating the coded pattern of the information section.

However, for practical reasons, electrically conductive materials like copper (Z=29), silver (Z=47), gold (Z=79), or the like, may be used, which may be easily distinguishable from any non-metal in the embedded chip-package 100, and/or for example aluminum (Z=13), which may possibly be undistinguishable in X-ray and/or ultrasound imaging from silicon (Z=14), but easily distingushable from carbon-based materials like polymers.

The pattern of electrically conductive portions and electrically insulating portions may in various embodiments include a plurality of vertically elongated electrically conductive portions, wherein at least two of the vertically elongated electrically conductive portions differ in diameter and/or in length.

An exemplary embodiment of such a configuration is shown in FIG. 1A and FIG. 1B.

The electrically conductive portions used in this embodiment for the encoding of the information in the information section I are vertical interconnects (vias) 112 that electrically conductively connect one of the metal layers 106, 116, namely the metal layer 106, with a first contact pad 108 of the chip 102 (wherein the first contact pad 108 may be arranged on a first side of the chip 102), and/or electrically conductively connect the other of the metal layers 106, 116, namely the metal layer 116, with a second contact pad 118 and/or a third contact pad 120 of the chip 102 (wherein the second contact pad 118 and the third contact pad 120 may be arranged on a second side of the chip 102 opposite the first side).

The vertical interconnects 112 may essentially be formed as known in the art, for example using laser drilling and/or an etching process using a mask.

As visualized in FIGS. 1A and 1B, the vertical interconnects 112 may be provided in two varieties, namely with a narrower diameter (112A) and with a broader diameter (112B), or with any other distinguishable shape, e. g., circular, square, star-shaped, etc. For easier distinction, they are additionally shown in different greyscales. The difference in diameter may for example be obtained by laser beams with different diameters and/or varying a motion pattern of the laser during a forming of openings in the electrically insulating material 104, and/or using an etching process using a structured mask with pre-defined mask openings with different diameters.

The coded information in the information section I that is provided as the pattern of electrically conductive portions and electrically insulating portions is, in the embodiment of FIGS. 1A and 1B that include the pattern of vertical interconnects with a narrower diameter 112A and vertical interconnects with a broader diameter 112B, in the annular regions extending from the narrower diameter to the broader diameter. This annular region is either filled by the metal of the (broader) vertical interconnect 112B, or by the insulating material 104 through which the vertical interconnect 112A extends. Thereby, a two-bit or two-dimensional coding may be provided.

In a case where a number of vertical interconnects may not need to be maximized (in other words, where one or more vertical interconnects may be omitted without compromising a performance of the embedded chip-package), a three-bit coding (i. e., adding one bit) may be made possible by optionally omitting the vertical interconnect 112 at one or more predefined positions (e. g., at predefined position in a two-dimensional matrix).

Further bits may be added (not shown in the figures) by alternatively or additionally varying a length of the vertical interconnects 112 (which may degrade the “vertical interconnects” to “vertical dummy interconnects”, since a shortening (some) of the interconnects 112 may mean that they do not reach the respective contact pad 108, 118, 120 any more. A variable length of the vertical interconnects 112 may for example be achieved by forming openings in the electrically insulating material 104 that extend either fully or only partially from an outer surface of the embedded chip-package 100 towards the chip 102, and then filling the opening with electrically conductive material.

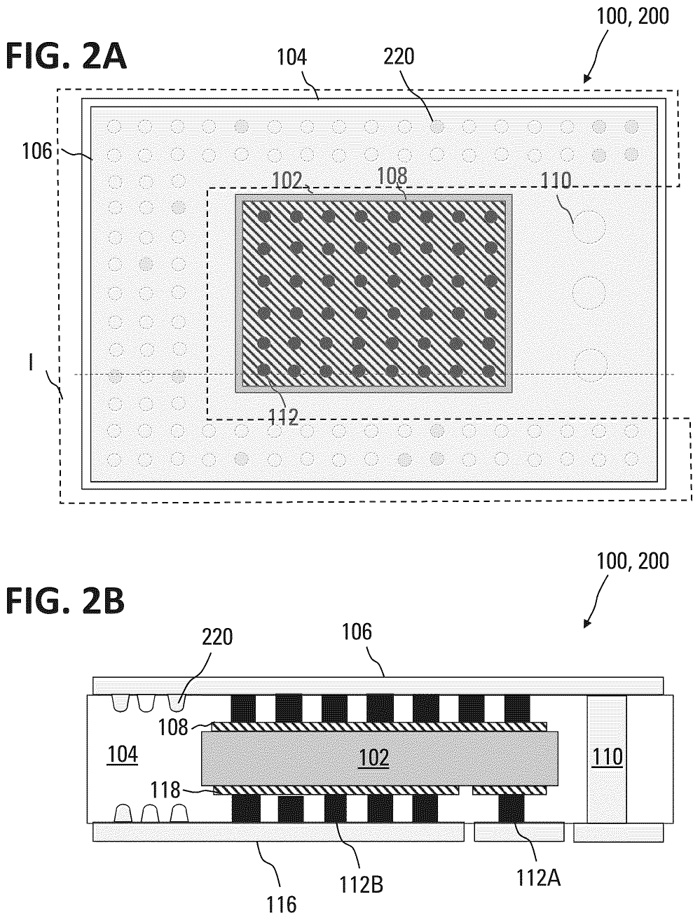

FIG. 2A shows a schematic top view of an embedded chip-package 100 in accordance with various embodiments, and FIG. 2B shows a schematic cross-sectional view of the embedded chip-package 100 of FIG. 2A along the horizontal line in FIG. 2A.

In the embodiment of FIGS. 2A and 2B, another type of vertically elongated electrically conductive portions 220 is provided in the information section I. In the top view of FIG. 2A, locations of a two-dimensional matrix are indicated where the vertically elongated electrically conductive portions 220 may optionally be formed. At several of those locations, the vertically elongated electrically conductive portions 220 may be arranged with at least one electrically unconnected end. Therefore, the vertically elongated electrically conductive portions 220 shown in FIGS. 2A and 2B may also be referred to as dummy vias 220.

The dummy vias 220 may be electrically and physically connected to the metal layer 106 or 116, respectively, and may extend vertically from one or both outer main surfaces of the electrically insulating material 104 towards a central plane of the embedded chip-package 100.

Thereby, they may additionally serve as anchors for the metal layer 106, 116.

The anchoring functionality of the dummy vias 220 may be have a positive effect that may be independent of the coding functionality.

Therefore, in FIGS. 2A and 2B, an exemplary embodiment of the embedded chip-package is additionally identified as an embedded chip-package 200.

The embedded chip-package 200 of various embodiments may include a chip 102, an electrically insulating material 104 at least partially encapsulating the chip 102, at least one metal layer 106, 116 configured to provide at least one electrically conductive connection to the chip 102, and at least one vertically elongated electrically conductive portion 220 including a first end connected to the at least one metal layer 106, 116 and a second end arranged in the electrically insulating material 104, wherein the second end is electrically unconnected.

Apart from the differences described in context with the embedded chip-package 200, it may be similar or identical to the embedded chip-package 100. Instead of coding information, and thus combining locations in the two-dimensional pattern that are provided with the dummy vias 220 with locations that are not provided with the dummy vias 220, the embedded chip-package 200 may have all locations provided with dummy vias 220, or may have the locations provided with the dummy vias 220 defined solely based on the anchoring functionality provided thereby.

In various embodiments, patterns formed by the dummy vias 220 on a first side of the embedded chip-package 200 may mirror each other, or may be independent of each other.

Getting back to the coded information in the embedded chip-package 100, in various embodiments, the embedded chip-package 100 may include a coded pattern of dummy vias 220 on the first main side of the embedded chip-package 200, and may have a mirrored coded pattern of dummy vias 220 on the opposite second side of the embedded chip package 200. In other words, underneath each of the formed dummy vias 220, another formed dummy via 220 may be arranged, and locations in the two dimensional pattern that are not provided with a dummy via 220 on the first side are not provided with a dummy via 220 underneath on the second side.

Thereby, the coded information included in the information section I on the first side of the embedded chip-package 100 may be the same as the coded information included in the information section I on the second side of the embedded chip-package 100, thus provided in a redundant way.

The redundantly provided information may for example be advantageous in a case where, for example, a portion of the embedded chip-package 100 is covered by a metal portion that prevents a penetration of, e. g., X-rays, towards the information section on one of the sides of the embedded chip-package 100 even in a 3D-tomography. In that case, the information section I on the other side of the embedded chip-package 100 may be accessible by, e. g., X-rays.

In various embodiments, the patterns of the dummy vias 220 in the information section I on the first side may be different from those of the dummy vias 220 on the second side. Thereby, an amount of information that may be coded in the embedded chip-package 100 may be larger.

The information section I may be buried inside the embedded chip-package 100, for example as shown in FIGS. 1B and 2B, or it may be exposed at an outer surface of the embedded chip-package 100. For realizing such an embodiment, the metal layer 106 and/or the metal layer 116 may optionally be at least partially removed above the dummy vias 220.

In various embodiments, the pattern of electrically conductive portions and electrically insulating portions may be formed as a structured metal layer.

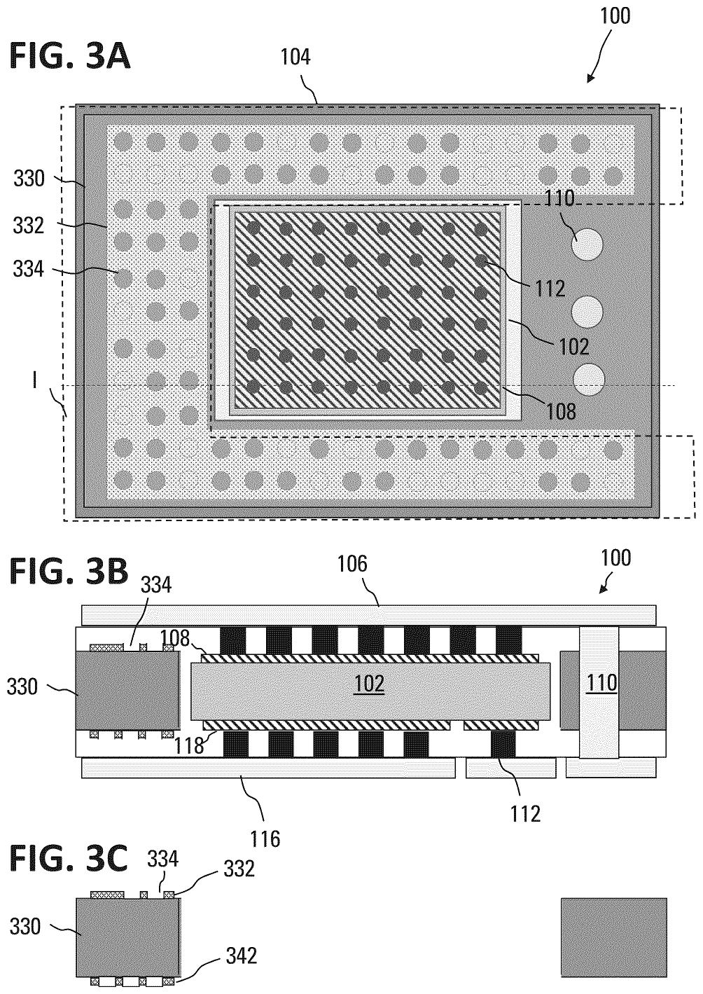

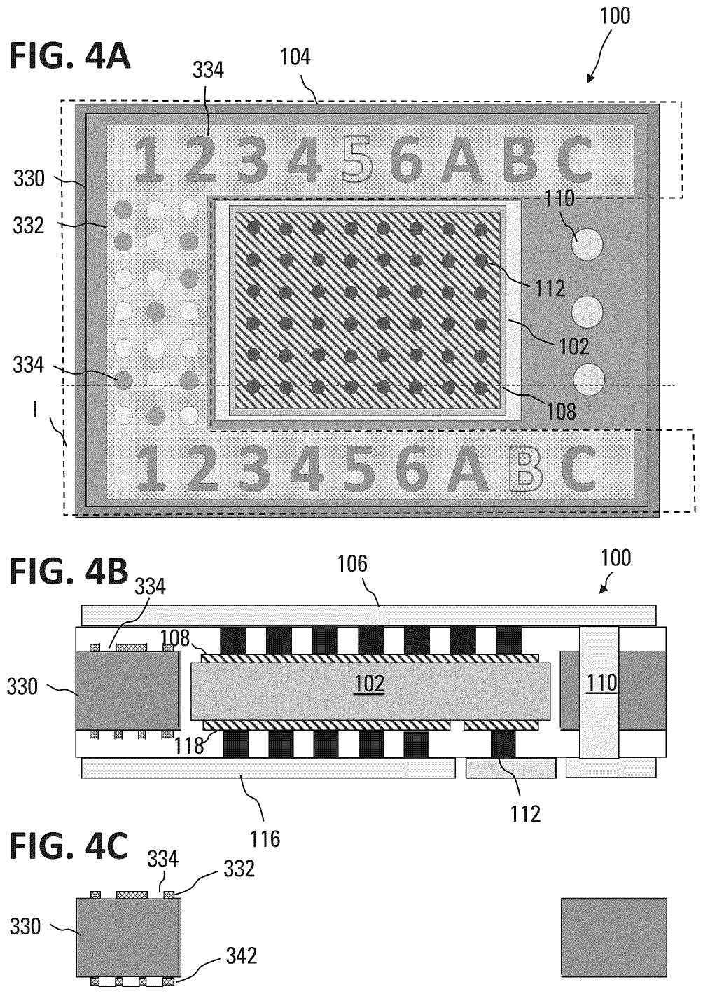

A corresponding exemplary embodiment is shown in FIGS. 3A to 3C and FIGS. 4A to 4C.

FIG. 3A shows a schematic top view of an embedded chip-package 100 in accordance with various embodiments, FIG. 3B shows a schematic cross-sectional view of the embedded chip-package 100 of FIG. 3A along the line shown in FIG. 3A, and FIG. 3C shows a schematic cross-sectional view of a core of the embedded chip-package 100 of FIGS. 3A and 3B.

FIG. 4A shows a schematic top view of an embedded chip-package 100 in accordance with various embodiments, FIG. 4B shows a schematic cross-sectional view of the embedded chip-package 100 of FIG. 4A along the line shown in FIG. 4A, and FIG. 4C shows a schematic cross-sectional view of a core of the embedded chip-package 100 of FIGS. 4A and 4B.

The embedded chip-package 100 may include a core 330. The core 330 may include an opening in which the chip 102 may be arranged. Even though the opening is shown as a through-hole, with vias contacting the chip 102 from both sides, this may not need to be the case. The opening may be formed as a cavity that is open only to one main side of the core, or as a partial through-hole, which may for example form a frame on which the chip 102 may rest, but which may have a further opening providing access to the side of the chip that rests on the frame.

The core 330 may in various embodiments include or consist of an electrically insulating material, or for example an electrically conductive, low-Z material like carbon. This may allow a provision of the information section I on one or both main surfaces(s) of the core 330 or inside the core 330 (not shown) in a way that is readable by, for example, X-ray and/or ultrasound diagnostics.

In FIG. 3A, one or more metal layer(s) 332, 342 are arranged on a first (main) side of the core 330 and/or on an opposite second (main) side of the core 330. The metal layer(s) 332, 342 may for example include or consist of typical metallization/RDL materials like copper, but may also include or consist of silver, gold, titanium, etc., and in a case of a low-Z core, also for example aluminum.

The information coding as the pattern of electrically conductive portions and electrically insulating portions may be provided by selectively removing the metal layer(s) 332, 342 in predefined locations, thereby forming the insulating portions 334 (which may, at a later stage, for example during an encapsulation process, be filled by the electrically insulating material 104), and by leaving the metal layer(s) 332, 342 in place in other predefined locations. Thus, the exemplary embodiment of FIG. 3A may again show a two-bit coding possibility for the information section I.

FIGS. 4A to 4C show a representation of various exemplary embodiments with a similar configuration like in FIGS. 3A to 3C. Here, letters and/or numbers may be provided in the information section I (additionally, but it is also possible to provide them instead of the two-dimensional array of removed/remained portions).

In various embodiments, the pattern of electrically conductive portions and electrically insulating portions may be provided by selectively forming the metal layer(s) 332, 342 in predefined locations, e. g. by structured deposition.

For the information provided on the first side and the second side of the core 330, a similar reasoning regarding redundant vs. non-redundant information applies as provided above in context with the dummy vias 220. In principle, any two sub-parts of all information sections I included in the embedded chip-package 100 may generally be considered for either redundant or independent information coding, for example the two “arms” of the “U” in FIG. 3A or FIG. 4A, respectively, or the like.

Even though the information section I formed as part of a metal layer 332, 334 was shown as an illustrative example of providing the information section buried within the embedded chip-package 100, any metal layer of the embedded chip-package 100, in particular any portion of the redistribution layers of the embedded chip-package 100, may be used as the information section I. For example, the metal layers 106, 116 may be used, for example portions of the metal layers 106, 116 that may not be foreseen to be directly electrically contacted when the embedded chip-package 100 is integrated into a PCB (in regions that will be directly electrically contacted, the electrically insulating portions of the coding pattern may get filled by interconnect material like solder or electrically conductive glue, which may make it difficult to identify those portions in diagnostic images).

The coded information about the embedded chip-package 100 may for example include properties of the embedded chip-package 100, for example a horizontal position of the chip 102 within the embedded chip-package 100, a vertical position of the chip 102 within the embedded chip-package 100, a lot ID, an ID of the embedded chip-package 100, and/or additional traceability data.

In various embodiments, a plurality of chips 102 may be included in the embedded chip-package 100.

In various embodiments, various information portions I may be included in a single embedded chip-package 100. For example, the diameters/lengths of the vertical interconnects 112 may be used in combination with the dummy vias 220 and/or with the structured metal layers 332, 342, and/or the structured metal layers 106, 116, etc.

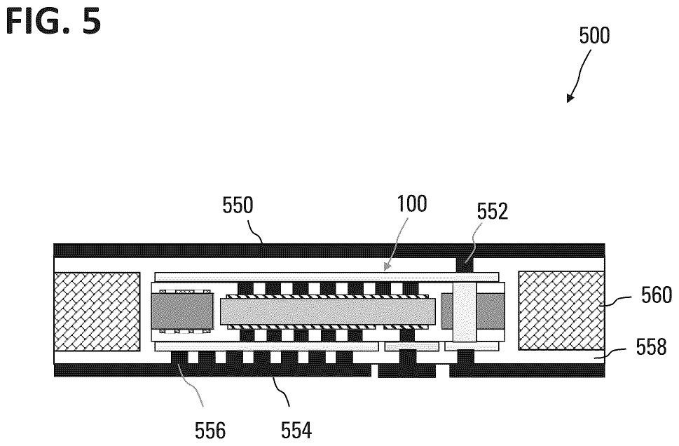

FIG. 5 shows a schematic cross-sectional view of a semiconductor package 500 in accordance with various embodiments.

The semiconductor package 500 includes at least one embedded chip-package 100 as described above, for example any of the embedded chip-packages 100 described in context with FIGS. 1A to 4C. Optionally, the semiconductor package 500 may include two or more embedded chip-packages 100.

The semiconductor package 500 may further include packaging material 558 at least partially encapsulating the embedded chip-package 100.

The semiconductor package 500 may for example form a printed circuit board (PCB) with the embedded chip-package 100 embedded as an inlay.

The semiconductor package 500 may further include electrically conductive contact areas 550, 554 on its main surfaces that may be used for electrically contacting the chip 102, for example in combination with vias 552, 556 electrically conductively connecting the contact areas 550, 554 with the metal layers 108, 118, and 120, respectively, and/or for mounting circuit components (not shown) that may be connected to the chip 102, for example capacitors, resistors, etc.

In various embodiments, the semiconductor package 500 may further include a package core 560, which may provide structural support and may be electrically insulating or electrically conductive, as required. The package core 560 may include an opening in which the embedded chip-package 100 may be arranged.

In various embodiments, a volume vertically above and/or below the information section I may be kept essentially free from metal to allow for X-ray imaging and/or ultrasound analysis of the information section I.

Generally, for retrieving the buried coded information from the embedded chip-package 100 in a non-destructive way, X-ray imaging and/or ultrasound analysis from a single direction may be sufficient in some cases. In other cases, where (e. g. functional) metal features like connection lines etc., may obscure at least part of the information section I when “seen” from a single direction, an X-ray tomography may be obtained, which may serve as a basis for a three-dimensional reconstruction of structures with different atomic numbers identified in the embedded chip-package 100, and/or ultrasound analysis may be performed from different directions.

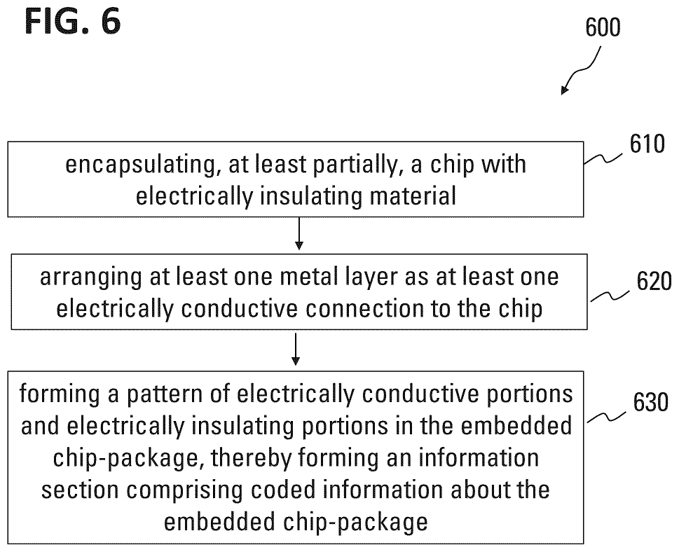

FIG. 6 shows a flow diagram 600 of a method of forming an embedded chip-package 100 in accordance with various embodiments

The method includes encapsulating, at least partially, a chip with electrically insulating material (610), arranging at least one metal layer as at least one electrically conductive connection to the chip (620), and forming a pattern of electrically conductive portions and electrically insulating portions in the embedded chip-package, thereby forming an information section comprising coded information about the embedded chip- package (630).

This method may be employed for forming the embedded chip-packages 100 described above in context with FIGS. 1A to 4C and other embodiments.

Various examples will be illustrated in the following:

Example 1 is an embedded chip-package. The embedded chip-package includes a chip, an electrically insulating material at least partially encapsulating the chip, at least one metal layer configured to provide at least one electrically conductive connection to the chip, and an information section including coded information about the embedded chip-package, wherein, in the information section, the information is coded as a pattern of electrically conductive portions and electrically insulating portions.

In Example 2, the subject-matter of Example 1 may optionally include that the pattern of electrically conductive portions and electrically insulating portions includes a plurality of vertically elongated electrically conductive portions, wherein at least two of the vertically elongated electrically conductive portions differ in diameter and/or in length.

In Example 3, the subject-matter of Example 2 may optionally include that at least one of the vertically elongated electrically conductive portions forms an electrically conductive connection between the chip and the at least one metal layer.

In Example 4, the subject-matter of Example 2 or 3 may optionally include that at least one of the vertically elongated electrically conductive portions has at least one electrically unconnected end.

In Example 5, the subject-matter of any of Examples 1 to 4 may optionally include that the information section includes a line or matrix of predefined pattern positions, and the pattern of electrically conductive portions and electrically insulating portions is distributed over the predefined pattern positions.

In Example 6, the subject-matter of any of Examples 1 to 5 may optionally include that the information section is exposed at an outer surface of the embedded chip-package.

In Example 7, the subject-matter of any of Examples 1 to 5 may optionally include that the information section is buried inside the embedded chip-package.

In Example 8, the subject-matter of any of Examples 1 to 7 may optionally include that the coded information is configured to be determinable at least via X-ray imaging, optionally also via ultrasound analysis, e. g. ultrasound imaging.

In Example 9, the subject-matter of any of Examples 1 to 8 may optionally include that the pattern of electrically conductive portions and electrically insulating portions is formed as a structured metal layer.

In Example 10, the subject-matter of Example 9 may optionally include that the structured metal layer is formed from a continuous metal layer by selectively removing the structured metal layer in the electrically insulating portions.

In Example 11, the subject-matter of Example 9 may optionally include that the structured metal layer is formed by selectively arranging the structured metal layer in the electrically conductive portions.

In Example 12, the subject-matter of any of Examples 1, 5, 7, or 8 may optionally include a carrier with an opening, wherein the chip is arranged in the opening, wherein the pattern of electrically conductive portions and electrically insulating portions is arranged over the carrier.

In Example 13, the subject-matter of any of Examples 1 to 12 may optionally include that the electrically insulating material includes at least one laminate layer.

In Example 14, the subject-matter of any of Examples 1 to 13 may optionally include that the pattern of electrically conductive portions and electrically insulating portions is a two-dimensional or a three-dimensional pattern.

In Example 15, the subject-matter of any of Examples 1 to 14 may optionally include that the coded information about the embedded chip-package includes at least one of a group of properties of the embedded chip-package, the group including or consisting of: a horizontal position of the chip within the embedded chip-package, a vertical position of the chip within the embedded chip-package, a lot ID, an ID of the embedded chip-package, and additional traceability data.

Example 16 is a semiconductor package. The semiconductor package includes the embedded chip-package of any of any of Examples 1 to 15 and packaging material at least partially encapsulating the embedded chip-package.

In Example 17, the subject-matter of Example 16 may form a printed circuit board (PCB) with the embedded chip-package embedded as an inlay.

In Example 18, the subject-matter of Example 16 or 17 may optionally include that a volume vertically above and/or below the information section is kept essentially free from metal to allow for X-ray imaging of the information section.

Example 19 is a method of forming an embedded chip-package. The method includes encapsulating, at least partially, a chip with electrically insulating material, arranging at least one metal layer as at least one electrically conductive connection to the chip, and forming a pattern of electrically conductive portions and electrically insulating portions in the embedded chip-package, thereby forming an information section comprising coded information about the embedded chip-package.

In Example 20, the subject-matter of Example 19 may optionally include that the forming the pattern includes forming a plurality of vertically elongated electrically conductive portions in such a way that at least two of the vertically elongated electrically conductive portions differ in diameter and/or in length.

In Example 21, the subject-matter of Example 20 may optionally include that at least one of the vertically elongated electrically conductive portions forms an electrically conductive connection between the chip and the at least one metal layer.

In Example 22, the subject-matter of Example 20 or 21 may optionally include that at least one of the vertically elongated electrically conductive portions has at least one electrically unconnected end.

In Example 23, the subject-matter of any of Examples 19 to 22 may optionally include that the information section includes a line or matrix of predefined pattern positions, and the pattern of electrically conductive portions and electrically insulating portions is distributed over the predefined pattern positions.

In Example 24, the subject-matter of any of Examples 19 to 23 may optionally include that the information section is exposed at an outer surface of the embedded chip-package.

In Example 25, the subject-matter of any of Examples 19 to 24 may optionally include that the information section is buried inside the embedded chip-package.

In Example 26, the subject-matter of any of Examples 19 to 25 may optionally include that the coded information is configured to be determinable at least via X-ray imaging.

In Example 27, the subject-matter of any of Examples 19 to 26 may optionally include that the pattern of electrically conductive portions and electrically insulating portions is formed as a structured metal layer.

In Example 28, the subject-matter of any of Example 27 may optionally include that the structured metal layer is formed from a continuous metal layer by selectively removing the structured metal layer in the electrically insulating portions.

In Example 29, the subject-matter of any of Example 27 may optionally include that the structured metal layer is formed by selectively arranging the structured metal layer in the electrically conductive portions.

In Example 30, the subject-matter of any of Examples 19, 23, 25, or 26 may optionally include a carrier with an opening, wherein the chip is arranged in the opening, wherein the pattern of electrically conductive portions and electrically insulating portions is arranged over the carrier.

In Example 31, the subject-matter of any of Examples 19 to 30 may optionally include that the electrically insulating material includes at least one laminate layer.

In Example 32, the subject-matter of any of Examples 19 to 31 may optionally include that the pattern of electrically conductive portions and electrically insulating portions is a two-dimensional or a three-dimensional pattern.

In Example 33, the subject-matter of any of Examples 19 to 32 may optionally include that the coded information about the embedded chip-package includes at least one of a group of properties of the embedded chip-package, the group including or consisting of: a horizontal position of the chip within the embedded chip-package, a vertical position of the chip within the embedded chip-package, a lot ID, an ID of the embedded chip-package, and additional traceability data.

In Example 34, the subject-matter of Example 19 or 20 may optionally include that the forming the pattern includes forming a structured metal layer by selectively removing of a prearranged metal layer or by selective deposition of a metal layer.

Example 35 is a method of forming a semiconductor package, the method including at least partially encapsulating the embedded chip-package of any of claims 1 to 15 with packaging material.

In Example 36, the method of Example 35 may further include inspecting the information section for retrieving the coded information about the embedded chip-package before the at least partially encapsulating the embedded chip-package.

Example 37 is a method of analyzing an embedded chip-package or a semiconductor package, the method including X-ray imaging of an embedded chip-package of any of Examples 1 to 15 or of a semiconductor package of any of Examples 16to 18 for retrieving the coded information about the embedded chip-package.

Example 38 is an embedded chip-package. The embedded chip-package includes a chip, an electrically insulating material at least partially encapsulating the chip, at least one metal layer configured to provide at least one electrically conductive connection to the chip, and at least one vertically elongated electrically conductive portion including a first end connected to the at least one metal layer and a second end arranged in the electrically insulating material, wherein the second end is electrically unconnected.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An embedded chip-package, comprising:
a chip;
electrically insulating material at least partially encapsulating the chip;
at least one metal layer configured to provide at least one electrically conductive connection to the chip; and
an information section comprising coded information about the embedded chip-package;
wherein, in the information section, the information is coded as a pattern of electrically conductive portions and electrically insulating portions.

2. The embedded chip-package of claim 1,
wherein the pattern of electrically conductive portions and electrically insulating portions comprises a plurality of vertically elongated electrically conductive portions, wherein at least two of the vertically elongated electrically conductive portions differ in diameter and/or in length.

3. The embedded chip-package of claim 2,
wherein at least one of the vertically elongated electrically conductive portions forms an electrically conductive connection between the chip and the at least one metal layer.

4. The embedded chip-package of claim 2,
wherein at least one of the vertically elongated electrically conductive portions has at least one electrically unconnected end.

5. The embedded chip-package of claim 1,
wherein the information section comprises a line or matrix of predefined pattern positions, and the pattern of electrically conductive portions and electrically insulating portions is distributed over the predefined pattern positions.

6. The embedded chip-package of claim 1,
wherein the information section is exposed at an outer surface of the embedded chip-package.

7. The embedded chip-package of claim 1,
wherein the information section is buried inside the embedded chip-package.

8. The embedded chip-package of claim 1,
wherein the coded information is configured to be determinable at least via X-ray imaging.

9. The embedded chip-package of claim 1,
wherein the pattern of electrically conductive portions and electrically insulating portions is formed as a structured metal layer.

10. The embedded chip-package of claim 9,
wherein the structured metal layer is formed from a continuous metal layer by selectively removing the structured metal layer in the electrically insulating portions.

11. The embedded chip-package of claim 9,
wherein the structured metal layer is formed by selectively arranging the structured metal layer in the electrically conductive portions.

12. The embedded chip-package of claim 1,
wherein the electrically insulating material comprises at least one laminate layer.

13. The embedded chip-package of claim 1,
wherein the pattern of electrically conductive portions and electrically insulating portions is a two-dimensional or a three-dimensional pattern.

14. The embedded chip-package of claim 1,
wherein the coded information about the embedded chip-package comprises at least one of a group of properties of the embedded chip-package, the group of properties consisting of:
a horizontal position of the chip within the embedded chip-package;
a vertical position of the chip within the embedded chip-package;
a lot ID;
an ID of the embedded chip-package; and
additional traceability data.

15. A semiconductor package, comprising:
the embedded chip-package of claim 1; and
packaging material at least partially encapsulating the embedded chip-package.

16. The semiconductor package of claim 15, comprising a printed circuit board (PCB) formed with the embedded chip-package embedded as an inlay.

17. The semiconductor package of claim 15,
wherein a volume vertically above and/or below the information section is kept free from metal to allow for X-ray imaging of the information section.

18. An embedded chip-package, comprising:
a chip;
electrically insulating material at least partially encapsulating the chip;
at least one metal layer configured to provide at least one electrically conductive connection to the chip; and
at least one vertically elongated electrically conductive portion comprising a first end connected to the at least one metal layer and a second end arranged in the electrically insulating material,
wherein the second end is electrically unconnected.
